(19) United States
(12) Patent Application Publication
(10) Pub. No.: US 2026/0173946 A1
(43) Pub. Date: Jun. 18, 2026

(54) BONDING STRUCTURE

(71) Applicant: Advanced Semiconductor Engineering, Inc., Kaohsiung (TW)

(72) Inventors: Fong Ren SIE, Kaohsiung (TW); Huang-Hsien CHANG, Kaohsiung (TW)

(73) Assignee: Advanced Semiconductor Engineering, Inc., Kaohsiung (TW)

(21) Appl. No.: 18/983,278

(22) Filed: Dec. 16, 2024

(51) Int. Cl. H01L 23/00

(52) U.S. Cl. CPC H10W 72/90; H10W 72/923; H10W 72/9415; H10W 72/952; H10W 80/701

(57) ABSTRACT

A bonding structure is provided. The bonding structure includes a lower pad and an upper pad. The lower pad includes a first nanotwin copper (NT-Cu) structure including a [111] crystallographic plane. The lower pad also includes a first non-NT-Cu structure encapsulating the first NT-Cu structure. The upper pad is bonded to the lower pad.

### BACKGROUND

### 1. Technical Field

The present disclosure relates generally to a bonding structure. Specifically, the present disclosure relates to a bonding structure including a nanotwin copper (NT-Cu) structure.

### 2. Description of the Related Art

Currently, redistribution structures typically consist of polycrystalline metal, which has lower resistance to electromigration. Additionally, the intermediate structure of an electronic device may undergo multiple heating processes, causing the metal crystal grain sizes to significantly increase and voids to form within the redistribution structure. This ultimately leads to a degradation in the performance of the electronic device. Therefore, a technical solution is required to address these issues.

### SUMMARY

In one or more arrangements, a bonding structure includes a lower pad and an upper pad. The lower pad includes a first nanotwin copper (NT-Cu) structure including a [111] crystallographic plane. The lower pad also includes a first non-NT-Cu structure encapsulating the first NT-Cu structure. The upper pad is bonded to the lower pad.

In one or more arrangements, a bonding structure includes a lower pad. The lower pad includes a first nanotwin copper (NT-Cu) structure having a [111] crystallographic plane and a first non-nanotwin copper (non-NT-Cu) structure. The first NT-Cu structure includes a protruding portion protruded from the first non-NT-Cu structure.

In one or more arrangements, a bonding structure includes a lower pad and an upper pad. The lower pad includes a first nanotwin copper (NT-Cu) structure. The upper pad includes a second NT-Cu structure. The lower pad is bonded to the upper pad. A twin boundary of the first NT-Cu structure is nonparallel to a twin boundary of the second NT-Cu structure.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1 is a cross-section of an electronic device in accordance with some arrangements of the present disclosure.

FIG. 2A is an enlarged view of the electronic device as shown in FIG. 1 in accordance with some arrangements of the present disclosure.

FIG. 2B is an enlarged view of the electronic device as shown in FIG. 1 in accordance with some arrangements of the present disclosure.

FIG. 2C is an enlarged view of the electronic device as shown in FIG. 1 in accordance with some arrangements of the present disclosure.

FIG. 3 is a cross-section of a bonding structure in accordance with some arrangements of the present disclosure.

FIG. 4A is an enlarged view of region A of the electronic device as shown in FIG. 1 in accordance with some arrangements of the present disclosure.

FIG. 4B is an enlarged view of region B of the electronic device as shown in FIG. 1 in accordance with some arrangements of the present disclosure.

FIG. 5A, FIG. 5B, FIG. 5C, FIG. 5D, FIG. 5E, FIG. 5F, and FIG. 5G illustrate various stages of an example of a method for manufacturing an electronic device in accordance with some arrangements of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

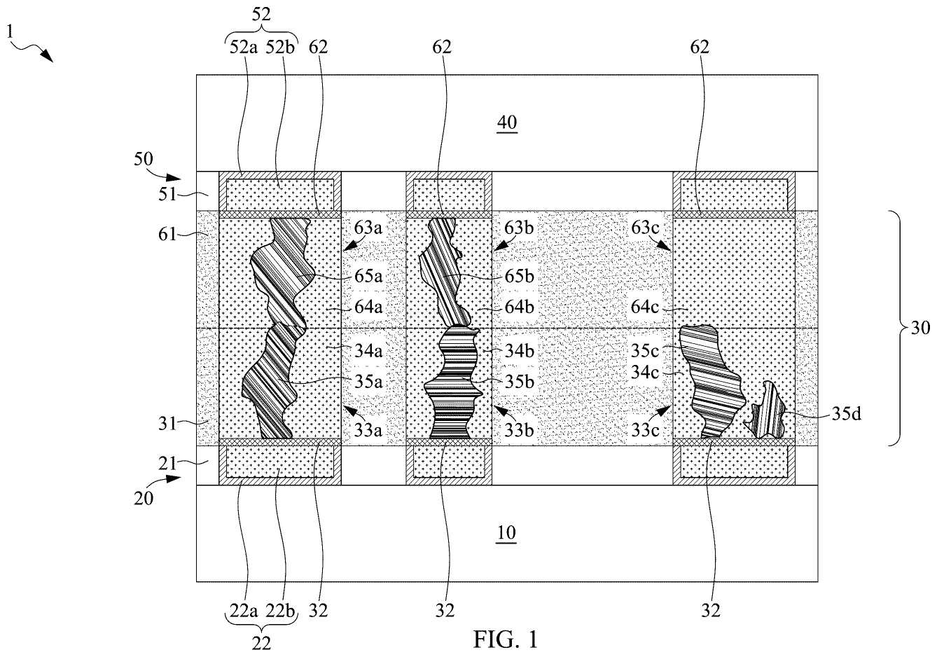

FIG. 1 is a cross-section of an electronic device 1 in accordance with some arrangements of the present disclosure. In some arrangements, the electronic device 1 may include a carrier 10, a redistribution structure 20, a hybrid-bond structure 30, a carrier 40, and a redistribution structure 50.

The carrier 10 (or lower carrier) may include a wafer (e.g., a silicon wafer), a silicon-based submount, an interposer (e.g., a glass interposer or a semiconductor interposer), a ceramic substrate, and/or other suitable carriers. In some arrangements, the carrier 10 may include a plurality of active elements (e.g., transistors, diodes, or other suitable elements) and/or passive elements (e.g., capacitors, inductors, or other suitable elements). In some arrangements, the carrier 10 may be a part of, for example, a printed circuit board, such as a paper-based copper foil laminate, a composite copper foil laminate, or a polymer-impregnated glass-fiber-based copper foil laminate.

The redistribution structure 20 may be disposed on or over the carrier 10. The redistribution structure 20 may be electrically connected between the carrier 10 and the hybrid-bond structure 30. The redistribution structure 20 may include a dielectric structure 21 and a conductive structure 22. The dielectric structure 21 may include one or more dielectric layers. The dielectric layer may include a single polymer material or composite polymer material(s) such as polyimide, polypropylene, polybenzoxazole, benzocyclobuten, or a combination thereof.

The conductive structure 22 may be encapsulated by the dielectric structure 21. The conductive structure 22 may include a layer 22a and a layer 22b. The layer 22a may include one or more functional layers. In some arrangements, the layer 22a may include a seed layer configured to assist in the formation of the layer 22b. In some arrangements, the layer 22a may include a barrier layer configured to prevent metal atoms of the layer 22b diffusing into the carrier 10. The layer 22a may include titanium, titanium nitride, tantalum/tantalum nitride, copper, or other suitable materials.

The layer 22b may be disposed on or over the layer 22a. In some arrangements, the layer 22b may include one or more conductive layers, such as silver, copper, aluminum, gold, or an alloy thereof. Although FIG. 1 illustrates that the layer 22b is spaced apart from the sidewall of the dielectric structure 21 by the layer 22a, the dielectric structure 21 may be in contact with the sidewall of the layer 22b in other arrangements.

The carrier 40 (or upper carrier) may include a wafer (e.g., a silicon wafer), a silicon-based submount, an interposer (e.g., a glass interposer or a semiconductor interposer), a ceramic substrate, and/or other suitable carriers. In some arrangements, the carrier 40 may include a plurality of active elements (e.g., transistors, diodes, or other suitable elements) and/or passive elements (e.g., capacitors, inductors, or other suitable elements). In some arrangements, the carrier 40 may be a part of, for example, a printed circuit board, such as a paper-based copper foil laminate, a composite copper foil laminate, or a polymer-impregnated glass-fiber-based copper foil laminate. In some arrangements, the carrier 40 may be electrically connected to the carrier 10 through the hybrid-bond structure 30.

The redistribution structure 50 may be disposed on or under the carrier 40. The redistribution structure 50 may be electrically connected between the carrier 40 and the hybrid-bond structure 30. The redistribution structure 50 may include a dielectric structure 51 and a conductive structure 52. The dielectric structure 51 may include one or more dielectric layers. The dielectric layer may include a single polymer material or composite polymer material(s) such as polyimide, polypropylene, polybenzoxazole, benzocyclobuten, or a combination thereof.

The conductive structure 52 may be encapsulated by the dielectric structure 51. The conductive structure 52 may include a layer 52a and a layer 52b. The layer 52a may include one or more functional layers. In some arrangements, the layer 52a may include a seed layer configured to assist in the formation of the layer 52b. In some arrangements, the layer 52a may include a barrier layer configured to prevent metal atoms of the layer 52b diffusing into the carrier 40. The layer 52a may include titanium, titanium nitride, tantalum/tantalum nitride, copper, or other suitable materials.

The layer 52b may be disposed on or over the layer 52a. In some arrangements, the layer 52b may include one or more conductive layers, such as silver, copper, aluminum, gold, or an alloy thereof. Although FIG. 1 illustrates that the layer 52b is spaced apart from the sidewall of the dielectric structure 51 by the layer 52a, the dielectric structure 51 may be in contact with the layer 52b in other arrangements.

In some arrangements, the hybrid-bond structure 30 (or bonding structure) may be disposed between the carriers 10 and 40. In some arrangements, the hybrid-bond structure 30 may be disposed between the redistribution structures 20 and 50. The hybrid-bond structure 30 may be formed by a hybrid-bond technique, which involves a bonding between dielectric layers and a bonding between metallic layers. A boundary or a non-obvious boundary (e.g., non-continuous boundary) may be generated at the bonding surface.

In some arrangements, the hybrid-bond structure 30 may include a dielectric layer 31 and a dielectric layer 61 bonded to the dielectric layer 31. The dielectric layer 31 may be disposed on or over the redistribution structure 20. The dielectric layer 61 may be disposed on or under the redistribution structure 50. The dielectric layers 31 and 61 may include oxide, nitride, oxynitride, carbide, or other suitable materials.

In some arrangements, the hybrid-bond structure 30 may include a seed layer 32 and conductive elements 33a, 33b, and 33c. The seed layer 32 may be disposed on or over the redistribution structure 20. The seed layer 32 may be in contact with the upper surface of the layer 22a and the upper surface of the layer 22b. The seed layer 32 may be configured to assist in the formation of the conductive elements 33a, 33b, and 33c. The seed layer 32 may include Cu, Cu alloy, Ti, Ti alloy, or any applicable seed layer material.

The conductive elements 33a, 33b, and 33c (or lower pads or lower pillars) may be spaced apart from each other by the dielectric layer 31. The conductive elements 33a, 33b, and 33c may function as a bonding element (e.g., a bonding pad) which is configured to be bonded to another conductive element, thereby defining a hybrid-bond structure. The conductive elements 33a, 33b, and 33c may have different widths. In some arrangements, the conductive elements 33a, 33b, and/or 33c may include a hybrid copper structure including a nanotwin (or nanotwinned) copper (NT-Cu) structure and a non-nanotwin (or nanotwinned) copper (non-NT-Cu) structure. For example, the conductive element 33a may include a non-NT-Cu structure 34a and an NT-Cu structure 35a. The conductive element 33b may include a non-NT-Cu structure 34b and an NT-Cu structure 35b. The conductive element 33c may include a non-NT-Cu structure 34c, an NT-Cu structure 35c and an NT-Cu structure 35d.

In some arrangements, the NT-Cu structure may refer to a structure having NT-Cu greater than or about 85 wt. % NT-Cu, greater than or about 90 wt. % NT-Cu, greater than or about 95 wt. % NT-Cu, greater than or about 98 wt. % NT-Cu, or more. In some arrangements, the non-NT-Cu structure may refer to a structure having NT-Cu less than or about 20 wt. % NT-Cu, less than or about 15 wt. % NT-Cu, less than or about 10 wt. % NT-Cu, less than or about 5 wt. % NT-Cu, or less.

In some arrangements, the term “nanotwin” may refer to two grains (or two portions of a crystal) are formed mirrored across a common crystallographic plane. In some arrangements, the term “nanotwin” may refer to two grains forming a nanotwin boundary (or twin boundary) between them. The nanotwin crystal structure may include a plurality of grains each including a plurality of nanotwin crystals (or “nanotwins”, “nanotwin layers”, or “multi-layers”) stacked in the common crystallographic plane.

Each the non-NT-Cu structures 34a, 34b, and 34c may be a polycrystalline structure. In some arrangements, each the non-NT-Cu structures 34a, 34b, and 34c may include a [100] crystallographic plane(s), a [110] crystallographic plane(s), and a [111] crystallographic plane(s). In some arrangements, the grains of the non-NT-Cu structures 34a, 34b, and 34c may substantially have no twin boundaries therebetween. In some arrangements, less than 5% of grains of the non-NT-Cu structures 34a, 34b, and 34c may have twin boundaries therebetween. In some arrangements, the grains of the non-NT-Cu structures 34a, 34b, and 34c may substantially have no twin boundaries between [111] crystallographic planes.

The NT-Cu structure 35a may be at least partially surrounded by the non-NT-Cu structure 34a. The NT-Cu structure 35a may be in contact with the non-NT-Cu structure 34a. The NT-Cu structure 35b may be at least partially surrounded by the non-NT-Cu structure 34b. The NT-Cu structure 35b may be in contact with the non-NT-Cu structure 34b. The NT-Cu structures 35c and 35d may be at least partially surrounded by the non-NT-Cu structure 34c. The NT-Cu structure 35c may be spaced apart from the NT-Cu structure 35d by the non-NT-Cu structure 34c. In some arrangements, the NT-Cu structures 35a to 35d may have a highly-oriented structure. In some arrangements, each the NT-Cu structures 35a to 35d may have a [111] crystallographic plane. In some arrangements, the NT-Cu structures 35a to 35d may be highly [111] oriented, suggesting that exceeding 85%, 90%, 95%, 98%, or 99% of grains within the NT-Cu structure possess a [111] crystallographic plane. In some arrangements, the NT-Cu structures 35a to 35d may have different dimensions (e.g., volume, area in a cross-section, width, length, thickness, and the like). In some arrangements, the NT-Cu structures 35a to 35d may have different profiles. In some arrangements, the number of NT-Cu structures of the conductive element 33c may be different from that of the conductive element 33a. In some arrangements, at least one of the NT-Cu structures may be in contact with a seed layer. For example, the NT-Cu structure 35a may be in contact with the seed layer 32.

In some arrangements, the hybrid-bond structure 30 may include a seed layer 62 and conductive elements 63a, 63b, and 63c. The seed layer 62 may be disposed on or under the carrier 40. The seed layer 62 may be in contact with the lower surface of the layer 52a and the lower surface of the layer 52b. The seed layer 62 may be configured to assist in the formation of the conductive elements 63a, 63b, and 63c. The seed layer 62 may include Cu, Cu alloy, Ti, Ti alloy, or any applicable seed layer material.

The conductive elements 63a, 63b, and 63c (or upper pads or upper pillars) may be spaced apart from each other by the dielectric layer 61. The conductive element 63a may be bonded to the conductive element 33a. The conductive element 63b may be bonded to the conductive element 33b. The conductive element 63c may be bonded to the conductive element 33c. The conductive elements 63a, 63b, and 63c may function as a bonding pad which is configured to be bonded to another conductive element, thereby defining a hybrid-bond structure. In some arrangements, the conductive element 63a, and/or 63b may include a hybrid copper structure including an NT-Cu structure and a non-NT-Cu structure. For example, the conductive element 63a may include a non-NT-Cu structure 64a and an NT-Cu structure 65a. The conductive element 63b may include a non-NT-Cu structure 64b and an NT-Cu structure 65b. Although FIG. 1 illustrates that the conductive element 63c does not have NT-Cu structures in this cross-section, the conductive element 63c may include NT-Cu in other cross-sections.

Each the non-NT-Cu structures 64a, 64b, and 64c may be a polycrystalline structure. In some arrangements, each the non-NT-Cu structures 64a, 64b, and 64c may include a [100] crystallographic plane(s), a [110] crystallographic plane(s), and a [111] crystallographic plane(s). In some arrangements, the grains of the non-NT-Cu structures 64a, 64b, and 64c may substantially have no twin boundaries therebetween. In some arrangements, less than 5% of grains of the non-NT-Cu structures 34a, 34b, and 34c may have twin boundaries therebetween. In some arrangements, the grains of the non-NT-Cu structures 64a, 64b, and 64c may substantially have no twin boundaries between [111] crystallographic planes.

The NT-Cu structure 65a may be at least partially surrounded by the non-NT-Cu structure 64a. The NT-Cu structure 65a may be in contact with the non-NT-Cu structure 64a. The NT-Cu structure 65b may be at least partially surrounded by the non-NT-Cu structure 64b. The NT-Cu structure 65b may be in contact with the non-NT-Cu structure 64b. In some arrangements, the NT-Cu structures 65a and 65b may have a highly-oriented structure. In some arrangements, each the NT-Cu structures 65a and 65b may have a [111] crystallographic plane. In some arrangements, the NT-Cu structures 65a and 65b may be highly [111] oriented, suggesting that exceeding 85%, 90%, 95%, 98%, or 99% of grains within the NT-Cu structure possess a [111] crystallographic plane. In some arrangements, the NT-Cu structures 65a and 65b may have different dimensions (e.g., volume, area in a cross-section, width, length, thickness, and the like). In some arrangements, the NT-Cu structures 65a and 65b may have different profiles.

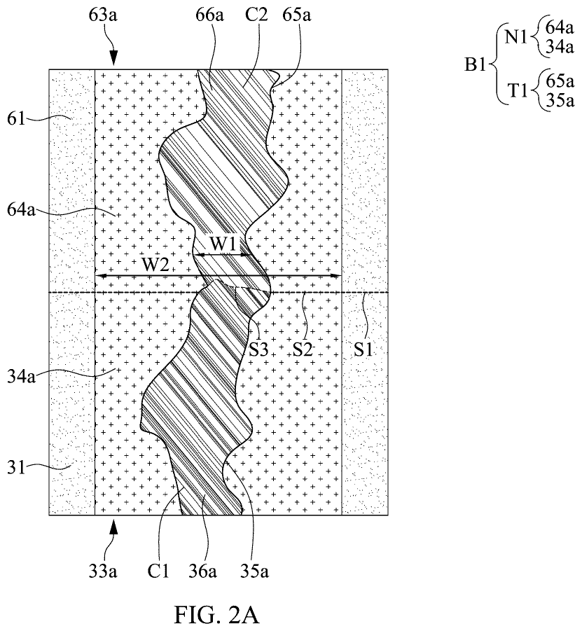

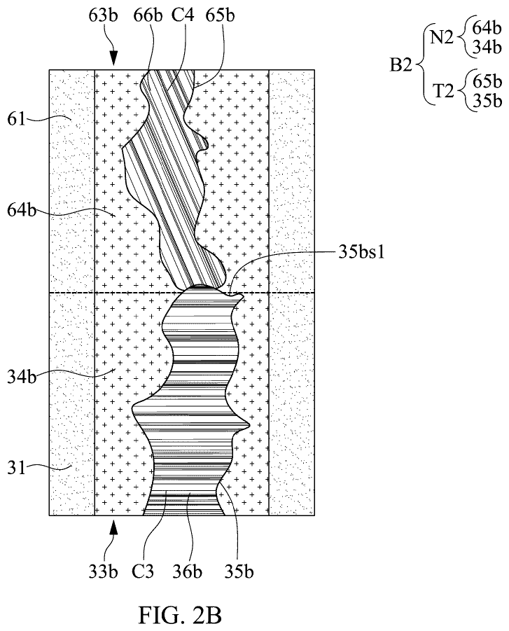

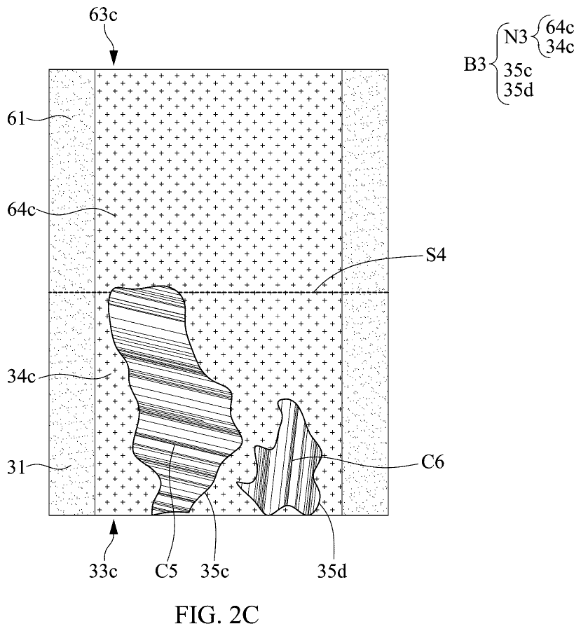

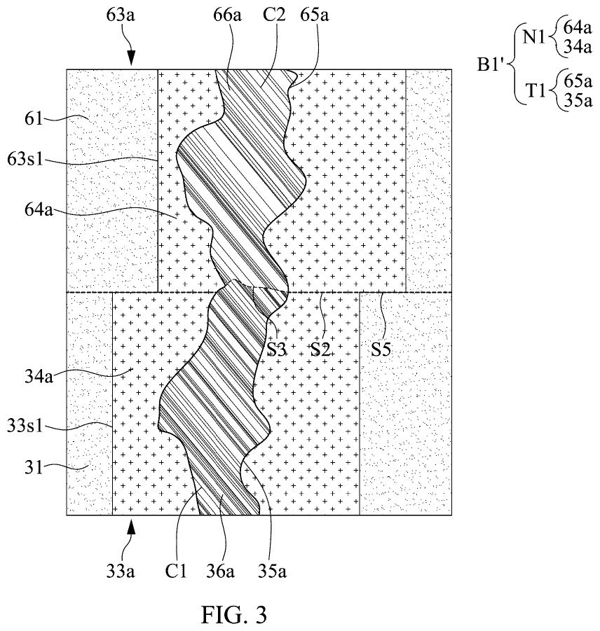

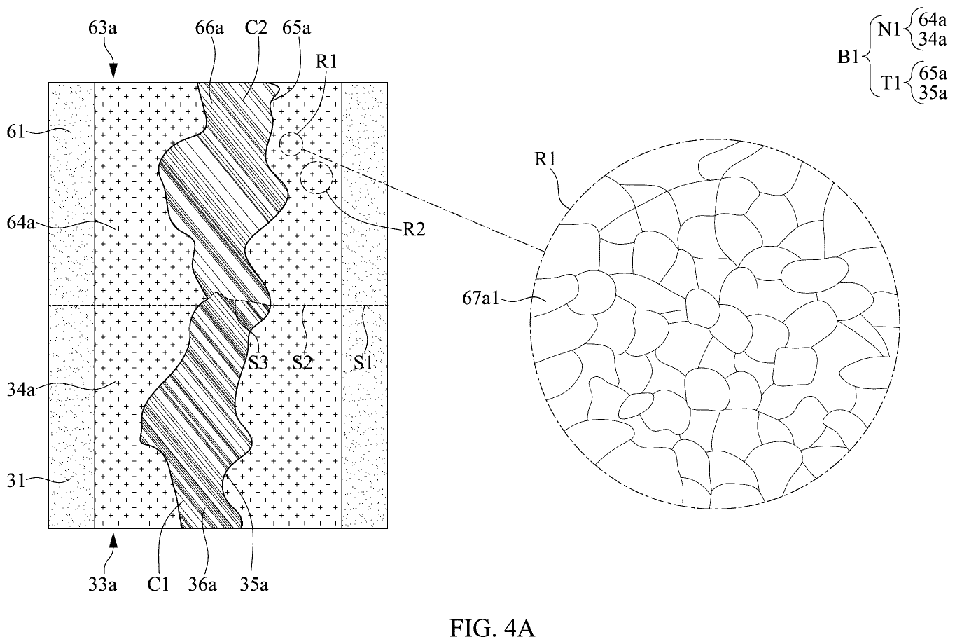

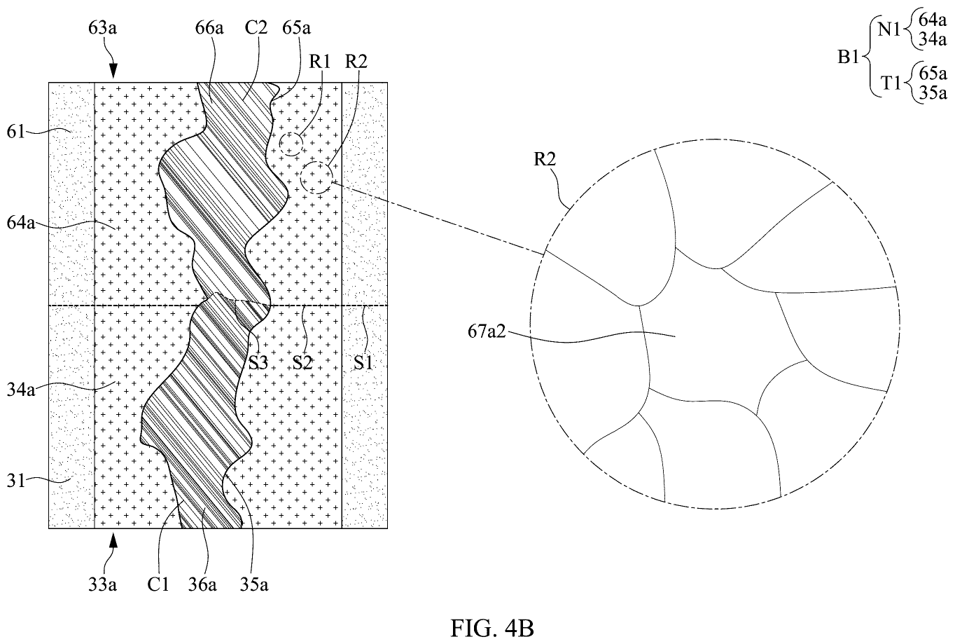

FIGS. 2A, 2B, and 2C are enlarged view of the bonded structures (or bonded conductive structures) B1, B2, and B3 as shown in FIG. 1 in accordance with some arrangements of the present disclosure.

Referring to FIG. 2A, the bonded structure B1 may be formed by bonding the conductive element 33a to the conductive element 63a. The bonding structure B1 may include a bonded non-NT-Cu (or non-NT-Cu structure or non-NT-Cu) N1 and a bonded NT-Cu (or NT-Cu structure or NT-Cu) T1. The bonded non-NT-Cu N1 may include the non-NT-Cu structures 34a and 64a. The bonded NT-Cu T1 may include the NT-Cu structures 35a and 65a. In some arrangements, the weight percentage of the bonded NT-Cu T1 with respect to the bonded structure B1 may range from about 1% to about 50%, such as 1%, 5%, 10%, 20%, 30%, 40%, or 50%. In some arrangements, the weight percentage of the bonded non-NT-Cu N1 may be greater than that of the bonded NT-Cu T1. In this arrangement, the bonded NT-Cu T1 may be regarded as a NT-Cu structure, and the NT-Cu structures 35a and 65a may be regarded as the first region and the second region of the bonded NT-Cu T1, respectively.

In some arrangements, the ratio of a width W1, along a lateral direction, of the bonded NT-Cu T1 to a width W2 of the bonded structure B1 may range between about 0.1 to about 0.8, such as 0.1, 0.2, 0.3, 0.4, 0.5, 0.6, 0.7, or 0.8. In this disclosure, the term “width” refers to the average width which is measured at multiple points. In some arrangements, an NT-Cu structure may have an uneven width along a lateral direction. For example, the NT-Cu structure 35a may have an uneven width along a lateral direction at different levels.

In some arrangements, the twin space of the bonded non-NT-Cu N1 may range from about 0.05 μm to about 2 μm, such as 0.05 μm, 0.1 μm, 0.5 μm, 1 μm, or 2 μm. In some arrangements, the boundaries C1 may have a distance ranging from about 0.05 μm to about 2 μm, such as 0.05 μm, 0.1 μm, 0.5 μm, 1 μm, or 2 μm.

In some arrangements, a boundary S1 between the dielectric layers 31 and 61 may be substantially aligned with a boundary S2 between the non-NT-Cu structures 34a and 64a. For example, the upper surface of the non-NT-Cu structure 34a may be substantially aligned with the upper surface of the dielectric layer 31.

In some arrangements, the upper surface of the non-NT-Cu structure 34a is exposed by the bonding surface S2. In some arrangements, a boundary S3 between the NT-Cu structures 35a and 65a may be misaligned with the boundary S2. For example, the boundary S3 may have a wave-shaped profile and protruded from the boundary S2. For example, the top of the NT-Cu structure 35a is higher than the top of the non-NT-Cu structure 34a. In some arrangements, the boundary S3 has a greater topography than the boundary S2 has in a cross-section. In some arrangements, the upper surface of the NT-Cu structure 35a is exposed by the bonding surface S3.

The NT-Cu structure has [111] crystallographic plane. Further, the NT-Cu structure is more compact than the non-NT-Cu structure. Therefore, the NT-Cu structure exhibits superior resistance to the slurry used in the CMP technique when compared to the non-NT-Cu structure. Furthermore, in certain instances, the diffusion rate of the NT-Cu structure is higher than that of the non-NT-Cu structure. For instance, the diffusion rate of the NT-Cu structure 35a surpasses that of the non-NT-Cu structure 34a. Consequently, a protruding portion of the NT-Cu structure 35a (or NT-Cu structure 65a), which diffuses into another NT-Cu structure and/or a non-NT-Cu structure, can be formed. This results in an enhancement of the bonding strength of the bonding structure (e.g., bonding structure B1) and allows for a reduction in the bonding temperature.

The NT-Cu structure 35a may vertically overlap the NT-Cu structure 65a. The NT-Cu structure 35a may include grains 36a. The grains 36a may define boundaries (or nanotwin boundaries) C1 therebetween. The NT-Cu structure 65a may include grains 66a. The grains 66a may define boundaries (or nanotwin boundaries) C2 therebetween. In some arrangements, the boundaries C1 may be substantially parallel to the boundaries C2. In some arrangements, the arrangement direction (or stacked direction) of the grains 36a may be substantially parallel to the arrangement direction (or stacked direction) of the grains 66a. In some arrangements, the extending direction of [111] crystallographic plane of the NT-Cu structure 65a may be substantially parallel to that of the NT-Cu structure 35a. In some arrangements, the boundaries C1 may not be connected to the C2. For example, the boundaries C1 and C2 may terminate at the boundary S3. In some arrangements, the extending direction of the grains 36a may be nonparallel to the boundary S3. In some arrangements, the grains 36a may have different lengths along their extending direction.

In some arrangements, the grain size (or average grain size) of the grains 36a of the NT-Cu structure 35a may be different from that of the grains 36b of the NT-Cu structure 35b. In some arrangements, the width (or average width) of the grains 36a of the NT-Cu structure 35a may be different from that of the grains 36b of the NT-Cu structure 35b.

Referring to FIG. 2B, the bonded structure B2 may be formed by bonding the conductive element 33b to the conductive element 63b. The bonding structure B2 may include a bonded non-NT-Cu N2 (or non-NT-Cu structure or non-NT-Cu) and a bonded NT-Cu T2 (or NT-Cu structure or NT-Cu). The bonded non-NT-Cu N2 may include the non-NT-Cu structures 34b and 64b. The bonded NT-Cu T2 may include the NT-Cu structures 35b and 65b. In some arrangements, the weight percentage of the bonded NT-Cu T2 with respect to the bonded structure B2 may range from about 1% to about 50%, such as 1%, 5%, 10%, 20%, 30%, 40%, or 50%.

In some arrangements, a portion of the NT-Cu structure 35b may be partially free from vertically overlapping the NT-Cu structure 65b. For example, a portion of the surface 35bs1 may be exposed by the NT-Cu structure 65b. In some arrangements, a portion of the surface 35bs1 may be in contact with the non-NT-Cu structure 64b. In some arrangements, the bonded NT-Cu T2 may have a step profile ST.

The NT-Cu structure 35b may include grains 36b. The grains 36b may define boundaries (or nanotwin boundaries) C3 therebetween. The NT-Cu structure 65b may include grains 66b. The grains 66b may define boundaries (or nanotwin boundaries) C4 therebetween. In some arrangements, the boundaries C3 may be nonparallel to the boundaries C4. In some arrangements, the arrangement direction (or stacked direction) of the grains 36b may be different from the arrangement direction (or stacked direction) of the grains 66b. In some arrangements, the extending direction of [111] crystallographic plane of the NT-Cu structure 65b may be nonparallel to that of the NT-Cu structure 35b. In some cases, the boundaries C3 may be more parallel to the polishing surface. As a result, the NT-Cu structure 35b demonstrates enhanced resistance to the slurry utilized in the CMP technique, leading to a reduced rate of removal compared to the non-NT-Cu structure 34b.

Referring to FIG. 2C, the bonded structure B3 may be formed by bonding the conductive element 33c to the conductive element 63c. The bonding structure B3 may include a bonded non-NT-Cu N3. The bonded non-NT-Cu N3 may include the non-NT-Cu structures 34c and 64c. In some arrangements, the NT-Cu structure 35c may protrude into the non-NT-Cu structure 64c because the diffusion speed of NT-Cu may be greater than that of the non-NT-Cu when bonding the conductive elements 33c and 63c. The NT-Cu structure 35c may be protruded from a boundary S4 between the non-NT-Cu structures 34c and 64c. In some arrangements, the NT-Cu structure 35d may be spaced apart from the non-NT-Cu structure 64c. In some arrangements, the NT-Cu structure 35d may be spaced apart from the boundary S4. In some arrangements, the boundaries C5 of the NT-Cu structure 35c may be nonparallel to boundaries C6 of the NT-Cu structure 35d. The extending direction of the [111] crystallographic plane of the NT-Cu structure 35c is nonparallel to that of the NT-Cu structure 35d. For example, the angle defined by the boundaries C5 and the boundary S4 may be different from the angle defined by the boundaries C6 and the boundary S4.

In this arrangement, a bonded structure is formed by bonding conductive elements with NT-Cu structures. Due to the superior diffusion speed of the NT-Cu structures, the bonded structure exhibits significantly fewer voids compared to a bonded structure without NT-Cu. As a result, the performance and/or yield of the electronic device 1 can be improved.

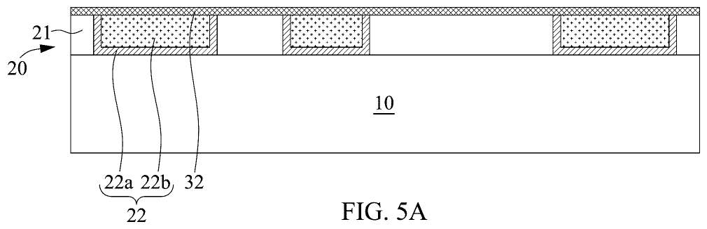

FIG. 3 is a cross-section of a bonding structure B1′ in accordance with some arrangements of the present disclosure.

In some arrangements, the upper pad may be misaligned with the lower pad. For example, a surface 33s1 (or lateral surface) of the conductive element 33a may be misaligned with a surface 63s1 (or lateral surface) of the conductive element 63a1. The surface 63s1 and the surface 33s1 may have a non-zero distance. In some arrangements, the bonded structure B1′ may include a boundary between a pad and a dielectric layer. For example, the bonded structure B1′ may include a boundary S5 between the conductive element 63a and the dielectric layer 31.

FIG. 4A and FIG. 4B are enlarged view of regions R1 and R2 of the electronic device 1 in accordance with some arrangements of the present disclosure.

The region R1 is closer to the bonded NT-Cu T1 than the region R2 is. As shown in FIG. 4A, the non-NT-Cu structure 64a may include multiple grains 67a1 within the region R1. As shown in FIG. 4B, the non-NT-Cu structure 64 a may include multiple grains 67a2 within the region R2. In some arrangements, one of the grains 67a1 may have a dimension (e.g., volume, width, area) less than that one of the grains 67a2. In some arrangements, the grain sizes of the grains of the non-NT-Cu structure decreases in a direction toward an NT-Cu structure. For example, the dimension (e.g., volume, width, area) of the grains 67a1 within the region R1 may be less than that of the grains 67a2 within the R2. Since the NT-Cu structure may restrain the growth of the grains of the non-NT-Cu structure after heating, the grains 67a1 may be smaller than the grains 67a2. As a result, the average grain size of the bonded structure B1 may be less than that of a comparative example. Therefore, the bonded structure (e.g., the bonded structure B1) of the electronic device (e.g., the electronic device 1) of the present disclosure can have a greater electromigration.

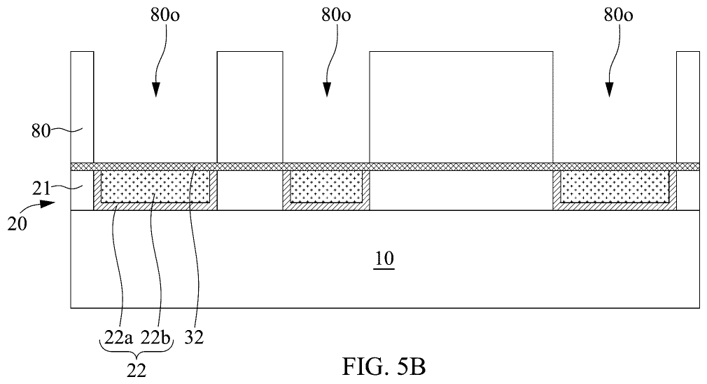

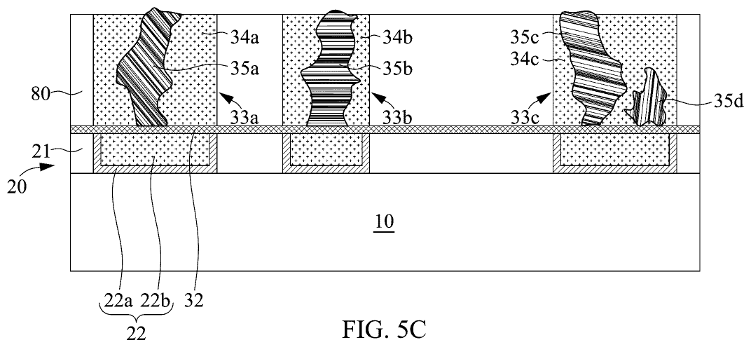

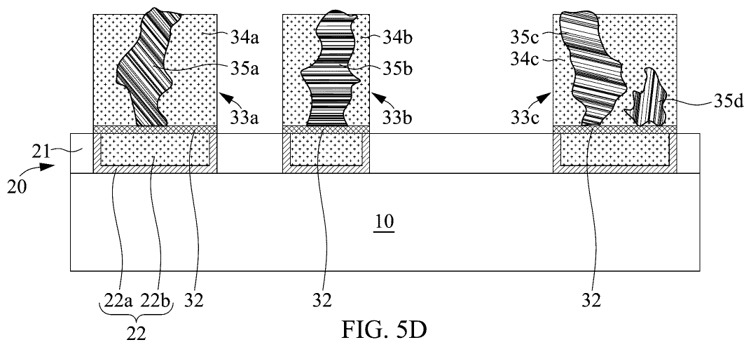

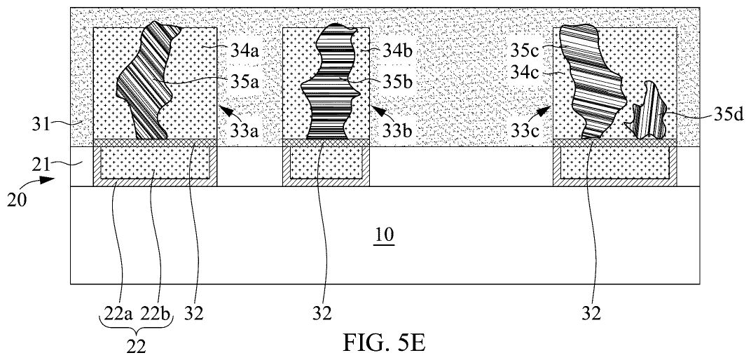

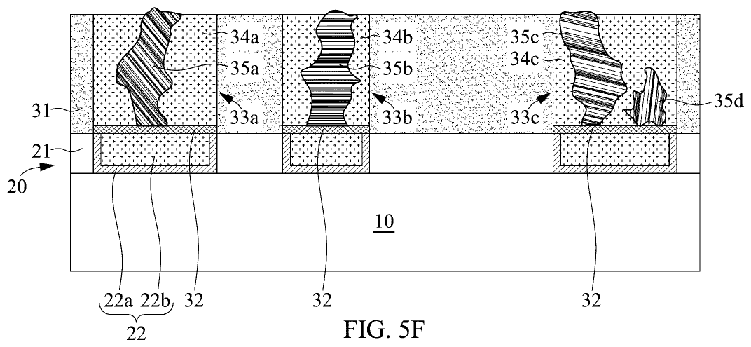

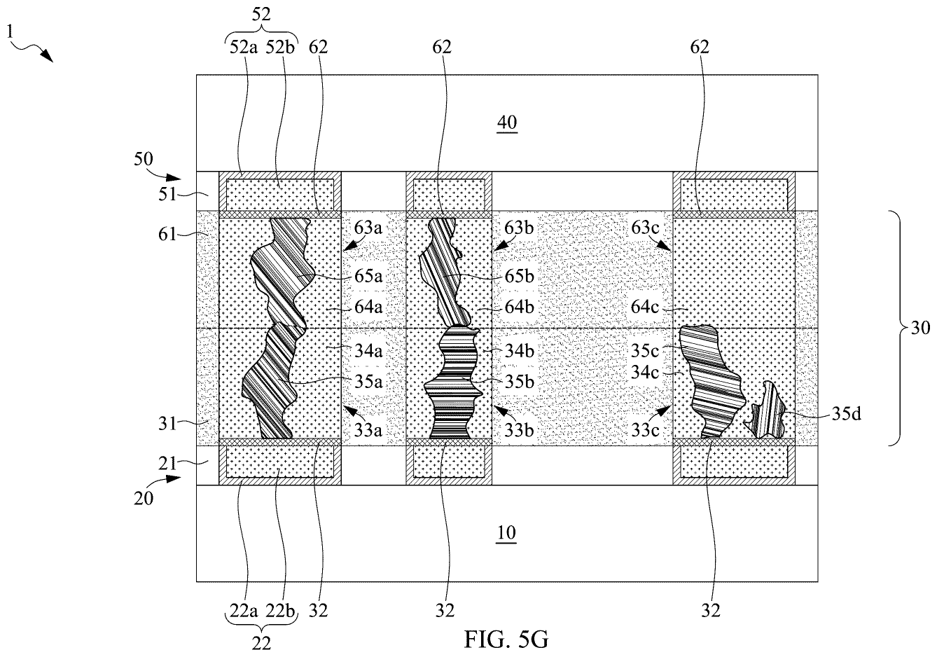

FIG. 5A, FIG. 5B, FIG. 5C, FIG. 5D, FIG. 5E, FIG. 5F, and FIG. 5G illustrate various stages of an example of a method for manufacturing an electronic device in accordance with some arrangements of the present disclosure.

Referring to FIG. 5A, the carrier 10 may be provided. The redistribution structure 20 may be formed on or over the carrier 10. The seed layer 32 may be formed on or over the redistribution structure 20.

Referring to FIG. 5B, a photosensitive material 80 may be formed on or over the seed layer 32. The photosensitive material 80 may be patterned to form openings 80o.

Referring to FIG. 5C, the conductive elements 33a, 33b, and 33c are formed. Each of the conductive elements 33a, 33b, and 33c may include a non-NT-Cu structure and an NT-Cu structure(s) within the non-NT-Cu structure.

Referring to FIG. 5D, the photosensitive material 80 may be removed. The lateral surface of the conductive elements 33a, 33b, and 33c may be exposed. The seed layer 32 under the photosensitive material 80 may be removed.

Referring to FIG. 5E, the dielectric layer 31 may be formed to cover the conductive elements 33a, 33b, and 33c.

Referring to FIG. 5F, a chemical mechanical polishing (CMP) technique may be performed. In some arrangements, a portion of the NT-Cu structure 35a may be protruded from the non-NT-Cu structure 34a due to the NT-Cu's higher resistance to the slurry used in CMP technique, as compared to the non-NT-Cu.

Referring to FIG. 5G, the carrier 40 may be provided. The redistribution structure 50 may be formed on or under the carrier 40. The dielectric layer 61 as well as the conductive elements 63a, 63b, and 63c may be formed on or under the redistribution structure 50. Next, the carrier 10 may be bonded to the carrier 40 by a hybrid-bond technique. The dielectric layer 31 may be bonded to the dielectric layer 61. The conductive elements 63a, 63b, and 63c may be bonded to the conductive elements 33a, 33b, and 33c, respectively to define the hybrid-bond structure 30. As a result, an electronic device (e.g., the electronic device 1) may be produced.

In one or more arrangements, a bonding structure includes a lower pad and an upper pad. The lower pad includes a first nanotwin copper (NT-Cu) structure including a [111] crystallographic plane. The lower pad also includes a first non-NT-Cu structure encapsulating the first NT-Cu structure. The upper pad is bonded to the lower pad.

In one or more arrangements, a bonding structure includes a lower pad and an upper pad. The lower pad includes a first nanotwin copper (NT-Cu) structure having a [111] crystallographic plane. The upper pad includes a second NT-Cu structure having a [111] crystallographic plane. The lower pad is bonded to the upper pad.

In one or more arrangements, a bonding structure includes a first bonded conductive structure and a second bonded conductive structure spaced apart from the first bonded conductive structure by a dielectric structure. The first bonded conductive structure includes a nanotwin copper (NT-Cu) structure.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of said numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” or “about” the same if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90°that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the singular terms “a,” “an,” and “the” may include plural referents unless the context clearly dictates otherwise. In the description of some arrangements, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific arrangements thereof, these descriptions and illustrations do not limit the present disclosure. It can be clearly understood by those skilled in the art that various changes may be made, and equivalent components may be substituted within the arrangements without departing from the true spirit and scope of the present disclosure as defined by the appended claims. The illustrations may not necessarily be drawn to scale. There may be distinctions between the artistic renditions in the present disclosure and the actual apparatus, due to variables in manufacturing processes and the like. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it can be understood that these operations may be combined, sub-divided, or re-ordered to form an equivalent method without departing from the teachings of the present disclosure. Therefore, unless specifically indicated herein, the order and grouping of the operations are not limitations of the present disclosure.

What is claimed is:

1. A bonding structure, comprising:
a lower pad, comprising:
a first nanotwin copper (NT-Cu) structure including a [111] crystallographic plane; and
a first non-NT-Cu structure encapsulating the first NT-Cu structure; and
an upper pad bonded to the lower pad.

2. The bonding structure of claim 1, wherein the first NT-Cu structure comprises a plurality of first grains extending along a first direction, and a bonding surface of the lower pad is nonparallel to the first direction.

3. The bonding structure of claim 1, wherein a top of the first NT-Cu structure is higher than a top of the first non-NT-Cu structure.

4. The bonding structure of claim 1, further comprising:
a first dielectric layer encapsulating the lower pad, wherein an upper surface of the first non-NT-Cu structure is substantially aligned with an upper surface of the first dielectric layer.

5. The bonding structure of claim 1, wherein the first NT-Cu structure has an uneven width along a lateral direction.

6. The bonding structure of claim 1, wherein the first NT-Cu structure has a step profile.

7. The bonding structure of claim 1, wherein the upper pad comprises a second NT-Cu structure including a [111] crystallographic plane, and the second NT-Cu structure is in contact with the first NT-Cu structure.

8. The bonding structure of claim 7, wherein a boundary between the first NT-Cu structure and the second NT-Cu structure has a wave-shaped profile.

9. The bonding structure of claim 7, wherein a dimension of the first NT-Cu structure is different from a dimension of the second NT-Cu structure.

10. The bonding structure of claim 7, wherein a portion of an upper surface of the first NT-Cu structure is exposed by the second NT-Cu structure.

11. The bonding structure of claim 1, wherein a weight percentage of the first NT-Cu structure with respect to the lower pad ranges from about 1% to about 50%.

12. The bonding structure of claim 1, wherein the lower pad is misaligned with the upper pad.

13. The bonding structure of claim 7, wherein the first NT-Cu structure comprises a plurality of first grains extending along a first direction, the second NT-Cu structure comprises a plurality of second grains extending along a second direction different from the first direction.

14. The bonding structure of claim 1, further comprising:
a first dielectric layer encapsulating the lower pad; and
a second dielectric layer encapsulating the upper pad,
wherein the lower pad, the upper pad, the first dielectric layer, and the second dielectric layer collectively define a hybrid-bond structure.

15. A bonding structure, comprising:
a lower pad comprising a first nanotwin copper (NT-Cu) structure having a [111] crystallographic plane and a first non-nanotwin copper (non-NT-Cu) structure, wherein the first NT-Cu structure comprises a protruding portion protruded from the first non-NT-Cu structure.

16. The bonding structure of claim 15, further comprising:
an upper pad bonded to the lower pad, wherein the protruding portion protrudes into the upper pad.

17. The bonding structure of claim 16, wherein the upper pad comprises a second NT-Cu structure in contact with the first NT-Cu structure.

18. The bonding structure of claim 16, wherein the upper pad comprises a second NT-Cu structure, and a twin boundary of the first NT-Cu structure is nonparallel to a twin boundary of the second NT-Cu structure.

19. A bonding structure, comprising:
a lower pad comprising a first nanotwin copper (NT-Cu) structure,
an upper pad comprising a second NT-Cu structure,
wherein the lower pad is bonded to the upper pad, and a twin boundary of the first NT-Cu structure is nonparallel to a twin boundary of the second NT-Cu structure.

20. The bonding structure of claim 19, wherein the lower pad comprises a first non-NT-Cu structure, the first non-NT-Cu structure comprises a plurality of grains, and grain sizes of the grains of the first non-NT-Cu structure decrease in a direction toward the first NT-Cu structure.
